(19) United States
(12) Patent Application Publication
(10) Pub. No.: US 2004/0152259 A1
(43) Pub. Date: Aug. 5, 2004

(54) Thin film capacitor and fabrication method thereof

(75) Inventor: Young-Hun Seo, Kyungki-do (KR)

Correspondence Address: PILLSBURY WINTHROP, LLP, P.O. BOX 10500, MCLEAN, VA, 22102, US

(73) Assignee: Anam Semiconductor Inc., Seoul (KR)

(21) Appl. No.: 10/747,110

(22) Filed: Dec. 30, 2003

(30) Foreign Application Priority Data
Jan. 30, 2003 (KR) 10-2003-0006347

(51) Int. Cl. H01L 21/8242; H01L 27/108; H01L 29/76; H01L 29/94; H01L 31/119

(52) U.S. Cl. 438/253; 438/255; 257/306; 257/309

(57) ABSTRACT

The present invention is directed to a thin film capacitor of a metal/insulator/metal (MIM) structure and a fabrication method thereof, which is capable of enabling small-sizing of a semiconductor device while maintaining electrostatic capacity of a capacitor. The fabrication method according to the present invention comprises the steps of: forming a plurality of grooves by selectively etching a lower insulation film on a structure of a semiconductor substrate; forming a first electrode layer, a dielectric layer and a second electrode layer in order on the lower insulation film on which the plurality of grooves are formed, such that a plurality of grooves are form in the first electrode layer, the dielectric layer and the second electrode layer, respectively, along a surface shape of the lower insulation film on which the plurality of grooves are formed; and selectively etching the second electrode layer, the dielectric layer and the first electric layer, leaving a predetermined width.

### BACKGROUND OF THE INVENTION

(a) Field of the Invention

The present invention relates to a fabrication method of a semiconductor device, and more particularly to a method for fabricating a thin film capacitor of a metal/insulator/metal (MI M) structure.

(b) Description of the Related Art

Recently, in a field of analog circuit requiring a high speed operation, semiconductor devices for realizing high capacitance have been developed. In general, since an upper electrode and a lower electrode of a capacitor are made of a conductive polysilicon in a case where the capacitor has a PIP structure where a polysilicon, an insulator, and a polysilicon are stacked in order, a natural oxide film is formed by an oxidation reaction at an interface between the upper and lower electrodes and a dielectric film, which results in reduction of the total capacitance.

To overcome this problem, the structure of capacitor has been changed to a metal/insulator/silicon (MIS) structure or a metal/insulator/metal (MIM) structure. Of these structures, since a capacitor of the MIM structure has a low specific resistance and no inner parasitic capacitance due to depletion, it is mainly used for high performance semiconductor devices.

Conventional techniques for a method for fabricating a thin film capacitor of the MIM structure are disclosed in U.S. Pat. Nos. 6,436,787, 6,426,250, 6,387,775, 6,271,084, and 6,159,793.

Hereinafter, a conventional method for fabricating a thin film capacitor of the MIM structure will be in brief described. FIG. 1 is a sectional view showing a thin film capacitor of a conventional MIM structure.

In order to fabricate the thin film capacitor of the MIM structure shown in FIG. 1, typical processes for fabricating a semiconductor device are first performed on a semiconductor substrate 1, a lower insulation film 2 is formed on the semiconductor substrate 1.

Next, a lower metal wire 3, a dielectric layer 4 and an upper metal wire 5 are formed in order on the lower insulation film 2.

Here, the lower metal wire 3 and the upper metal wire 5 correspond to first and second electrode layers, respectively, in the MIM capacitor.

Next, the upper metal wire 5 is selectively etched leaving a predetermined width, and then the dielectric layer 4 and the lower metal wire 3 is selectively etched leaving a predetermined width.

In the conventional MIM capacitor as described above, electrostatic capacity depends on a size of the upper metal wire 5.

However, as a size of device becomes reduced due to high integration of semiconductor devices, an area of the upper metal wire becomes smaller. Accordingly, there have been proposed various methods for reducing a thickness of the dielectric layer or increasing a contact area between metals while reducing an overall area without any reduction of electrostatic capacity. These methods are designed for improvement of an operation speed by increasing a coupling ratio in order to secure the electrostatic capacity.

However, with the methods for increasing the coupling ratio, there is a limit to reduction of the upper metal wire while maintaining the electrostatic capacity. Accordingly, there is a keen need for a new method.

### SUMMARY OF THE INVENTION

In considerations of the above problems, it is an object of the present invention to enable small-sizing of a semiconductor device while maintaining electrostatic capacity of a capacitor.

To achieve the object, there is provided a method for fabricating a thin film capacitor wherein grooves are formed by selectively etching a lower insulation film by a predetermined depth and then a first electrode layer, a dielectric layer and a second electrode layer are formed on the grooves.

According to an aspect of the present invention, a method for fabricating a thin film capacitor comprises the steps of: forming a plurality of grooves by selectively etching a lower insulation film on a structure of a semiconductor substrate; forming a first electrode layer, a dielectric layer and a second electrode layer in order on the lower insulation film on which the plurality of grooves are formed, such that a plurality of grooves are form in the first electrode layer, the dielectric layer and the second electrode layer, respectively, along a surface shape of the lower insulation film on which the plurality of grooves are formed; and selectively etching the second electrode layer, the dielectric layer and the first electric layer, leaving a predetermined width.

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIG. 1 is a sectional view showing a conventional thin film capacitor;

FIGS. 2a to 2d are sectional views showing a method for fabricating a thin film capacitor according to a first embodiment of the present invention; and

FIGS. 3a to 3d are sectional views showing a method for fabricating a thin film capacitor according to a second embodiment of the present invention.

### DETAILED DESCRIPTION OF THE PREFERRED EMBODIMENT

A thin film capacitor and a fabrication method thereof according to preferred embodiments of the present invention will now be described in detail with reference to the accompanying drawings.

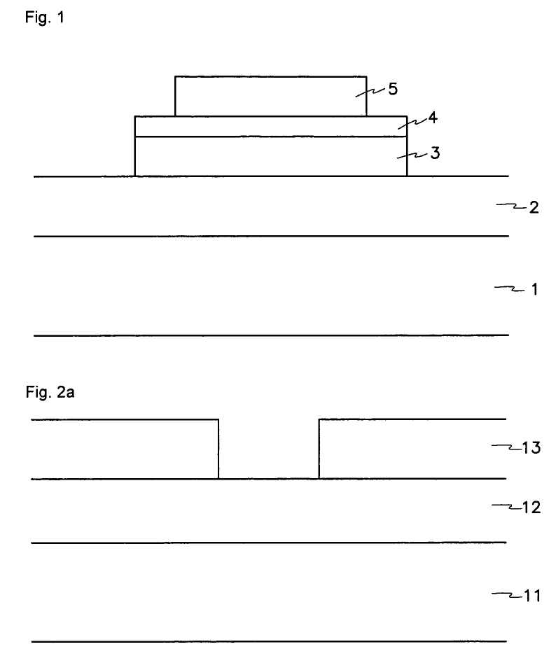

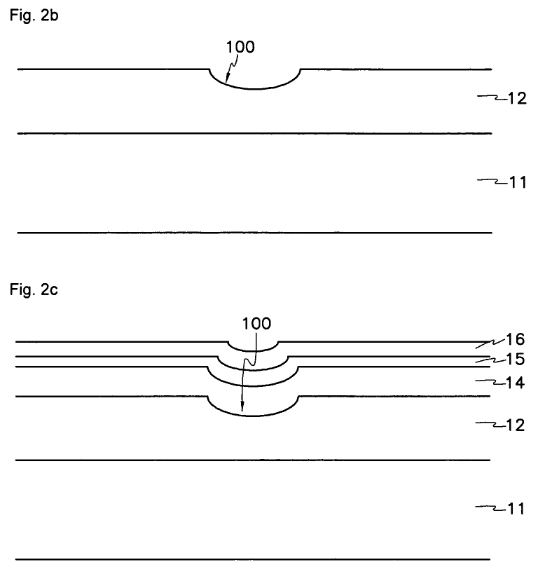

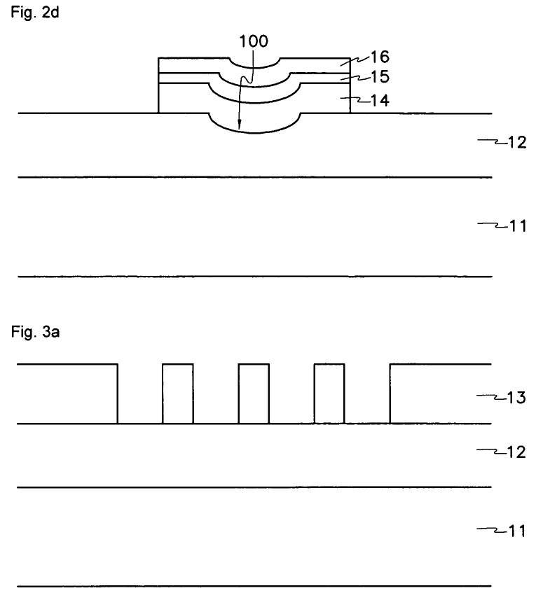

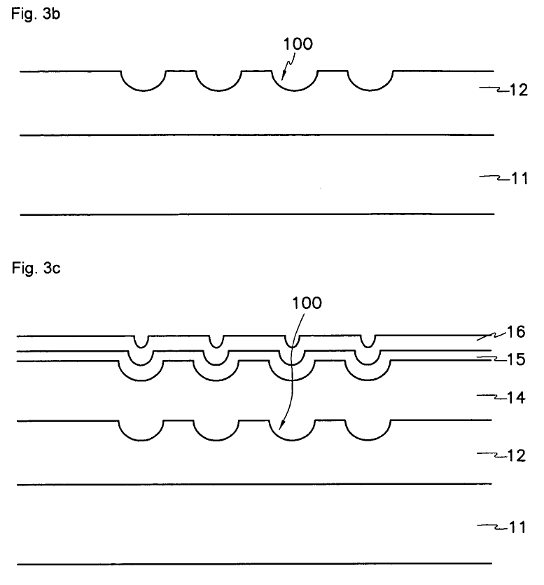

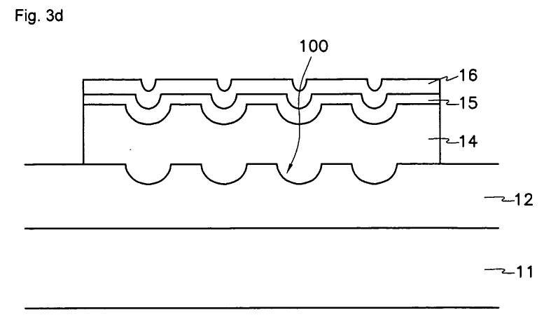

A thin film capacitor fabricated according to a first embodiment of the present invention is shown in FIG. 2d, a thin film capacitor fabricated according to a second embodiment of the present invention is shown in FIG. 3d, where a lower insulation film 12 and a thin film capacitor are sequentially formed on a structure 11 of a semiconductor substrate in which individual elements are formed.

A groove 100 is formed on a surface of the lower insulation film 12. At this time, the groove 100 can be formed by single as shown in FIG. 2d or by multiple as shown in FIG. 3d.

In addition, the groove formed on the surface of the lower insulation film 12 can be a circular groove having a curved inner surface and an arc section, or a rectangular groove having a flat inner surface and a section having a vertical edge angle or a curved edge.

A first electrode layer 14, a dielectric layer 15 and a second electrode 16 are formed on the lower insulation film 12 with a predetermined width along a surface shape of the lower insulation film 12. Accordingly, grooves are also formed on surfaces of the first electrode layer 14, the dielectric layer 15 and the second electrode 16.

The second electrode layer 16 can be made of one selected from a group consisting of W, Ti, TiN and Al.

Now, a method for fabricating the thin film capacitor of the present invention as described above will be in detail described.

FIGS. 2a to 2d are sectional views showing a method for fabricating the thin film capacitor according to the first embodiment of the present invention.

First, as shown in FIG. 2a, typical processes for fabricating a semiconductor device are first performed on a semiconductor substrate in order to form a structure 11 of the semiconductor substrate in which individual elements are formed, a lower insulation film 12 composed of an oxide film such as PSG is formed on the structure 11 of the semiconductor substrate, and then the lower insulation film 12 is planarized by a chemical and mechanical polishing process.

Subsequently, a photosensitive film is applied, exposed and developed on the planarized lower insulation film 12 such that a photosensitive film pattern 13 to expose the lower insulation film 12, located under a region to be formed with a capacitor, by a predetermined width is formed.

Next, as shown in FIG. 2b, a groove 100 is formed by etching the lower insulation film 12 exposed using the photosensitive film pattern 13 as a mask, the photosensitive film pattern 13 is removed, and then a cleaning process is performed.

At this time, an etching thickness and an etching shape of the lower insulation film 12 can be controlled depending on a user's need. As an example, a circular groove having a curved inner surface and an arc section by a wet etching of the lower insulation film is shown in FIG. 2b. However, the groove is not limited to the circular groove, but can be a rectangular groove having a flat inner surface and a section having a vertical edge angle or a curved edge.

Next, as shown in FIG. 2c, a lower metal wire 14 is formed by depositing a metal layer on the lower insulation film 12, in which the groove 100 is formed, along a surface shape of the lower insulation film 12. At this time, the lower metal wire 12 corresponds to a first electrode layer in a MIM capacitor structure.

Subsequently, a dielectric layer 15 is formed on the lower metal wire 14 along a surface shape of the lower metal wire 14, an upper metal wire 16 is formed by depositing a metal layer such as W, Ti, TiN or Al on the dielectric layer along a surface shape of the dielectric layer. At this time, the upper metal wire 16 corresponds to a second electrode layer in the MIM capacitor structure.

In this way, since the lower metal wire 14, the dielectric layer 15 and the upper metal wire 16 are formed along the surface shape of the lower insulation film in which the groove 100 is formed, consequently, grooves are also formed on the lower metal wire 14, the dielectric layer 15 and the upper metal wire 16. Namely, a shape of MIM in the MIM capacitor structure has a three dimensional shape due to the grooves, and accordingly, a curved contact area in the MIM according to the present invention is increased, compared to a flat contact area in a conventional MIM.

In addition, electrostatic capacity can be controlled by adjusting a depth of the groove formed by adjustment of an etching depth of the lower insulation film 12.

Finally, s shown in FIG. 2d, fabrication of the thin film capacitor having the MIM structure is completed by selectively etching the upper metal wire 16, the dielectric layer 15 and the lower metal wire 14, leaving a predetermined width.

On the other hand, FIGS. 3a to 3d are sectional views showing a method for fabricating a thin film capacitor according to a second embodiment of the present invention, where a pattern of a plurality of grooves is formed in the photosensitive film pattern 13, and a plurality of grooves are formed in the lower insulation film 12 using the photosensitive film pattern 13 as a mask.

Accordingly, a plurality of grooves exist on the lower metal wire 14, the dielectric layer 15 and the upper metal wire 16, respectively, which are formed on the lower insulation film 12.

As described above, according to the present invention, since the groove is formed in the lower insulation film and the thin film capacitor having the MIM structure is formed thereon, the contact area of the second electrode layer is increased, accordingly electrostatic capacity of the capacitor can be increased.

Accordingly, electrostatic capacity of a capacitor in small-sized semiconductor devices can be secured.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A thin film capacitor including a first electrode layer of a predetermined width formed on a lower insulation film on a structure of a semiconductor substrate, a dielectric layer formed on the first electrode layer, and a second electrode layer formed on the dielectric layer,
wherein a plurality of grooves are formed on a surface of the lower insulation film, and
wherein the first electrode layer is formed along a surface shape of the lower insulation film such that a plurality of grooves are formed on surfaces of the first electrode layer, the dielectric layer and the second electrode layer, respectively.

2. The thin film capacitor of claim 1, wherein the groove formed on the surface of the lower insulation film is one of a circular groove having a curved inner surface and an arc section, a rectangular groove having a flat inner surface and a section having a vertical edge angle, and a rectangular groove having a flat inner surface and a section having a curved edge.

3. The thin film capacitor of claim 2, wherein the second electrode layer is made of material selected from a group consisting of W, Ti, TiN and Al.

4. A method for fabricating a thin film capacitor, comprising the steps of:
forming a plurality of grooves by selectively etching a lower insulation film on a structure of a semiconductor substrate; and
forming a first electrode layer, a dielectric layer and a second electrode layer in order on the lower insulation film on which the plurality of grooves are formed, such that a plurality of grooves are form in the first electrode layer, the dielectric layer and the second electrode layer, respectively, along a surface shape of the lower insulation film on which the plurality of grooves are formed.

5. The method of claim 4, wherein, in the step of forming the plurality of grooves by selectively etching the lower insulation film, the plurality of grooves are formed in the lower insulation film by planarizing the lower insulation film by a chemical and mechanical polishing process, applying, exposing and developing a photosensitive film on the planarized lower insulation film such that a photosensitive film pattern to expose the lower insulation film located under a region to be formed with the grooves, and selectively etching the lower insulation film exposed using the photosensitive film pattern as a mask by a predetermined depth.

6. The method of claim 5, wherein, in the step of forming the plurality of grooves by selectively etching the lower insulation film, one of a circular groove having a curved inner surface and an arc section, a rectangular groove having a flat inner surface and a section having a vertical edge angle, and a rectangular groove having a flat inner surface and a section having a curved edge is formed by selectively etching the lower insulation film exposed using the photosensitive film pattern as a mask by a predetermined depth.

7. The method of claim 6, wherein, in the step of forming the second electrode layer, material selected from a group consisting of W, Ti, TiN and Al is formed on the dielectric layer.

8. The method of claim 4, further comprising a step of, after the step of forming the first electrode layer, the dielectric layer and the second electrode layer, selectively etching the second electrode layer, the dielectric layer and the first electrode layer, leaving a predetermined width.

9. The method of claim 5, further comprising a step of, after the step of forming the first electrode layer, the dielectric layer and the second electrode layer, selectively etching the second electrode layer, the dielectric layer and the first electrode layer, leaving a predetermined width.

10. The method of claim 6, further comprising a step of, after the step of forming the first electrode layer, the dielectric layer and the second electrode layer, selectively etching the second electrode layer, the dielectric layer and the first electrode layer, leaving a predetermined width.

11. The method of claim 7, further comprising a step of, after the step of forming the first electrode layer, the dielectric layer and the second electrode layer, selectively etching the second electrode layer, the dielectric layer and the first electrode layer, leaving a predetermined width.
